(19) United States
(12) Patent Application Publication
(10) Pub. No.: US 2026/0068778 A1
(43) Pub. Date: Mar. 5, 2026

(54) PACKAGE SEMICONDUCTOR

(71) Applicant: Samsung Electronics Co., Ltd., Suwon-si (KR)

(72) Inventor: Jihyun LEE, Suwon-si (KR)

(73) Assignee: Samsung Electronics Co., Ltd., Suwon-si (KR)

(21) Appl. No.: 19/061,191

(22) Filed: Feb. 24, 2025

(30) Foreign Application Priority Data
Aug. 29, 2024 (KR) 10-2024-0117033

(51) Int. Cl. H01L 23/498; H01L 21/48; H01L 23/31; H01L 23/538; H01L 25/07

(52) U.S. Cl. CPC H01L 23/49816

(57) ABSTRACT

Provided is a package semiconductor including a package substrate including a pad, an interposer, a column that is formed at a position corresponding to the pad, a solder that is formed between the pad and the column, a first semiconductor chip that is placed on the interposer, and a second semiconductor chip that is placed spaced apart from the first semiconductor chip, wherein the interposer includes a first area between the first semiconductor chip and the second semiconductor chip and a second area that is an area other than the first area, the solder includes a fist solder of which at least a portion is placed at a position corresponding to the first area, and a second solder of which at least a portion is placed at a position corresponding to the second area, and the first solder has volume that is greater than volume of the second solder.

### CROSS-REFERENCE TO RELATED APPLICATIONS

This application claims the benefit of Korean Patent Application No. 10-2024-0117033, filed on Aug. 29, 2024, in the Korean Intellectual Property Office, the disclosure of which is incorporated herein by reference in its entirety.

### BACKGROUND

### 1. Field of the Invention

Example embodiments relate to a package semiconductor.

### 2. Description of the Related Art

With the rapid development of the electronics industry and the demands of users, electronic devices are becoming smaller, more capacitive, and more multifunctional. To implement these functions, a package semiconductor containing multiple semiconductor chips is required (or may be advantageous). Package semiconductors that introduce an interposer for high integration may be known. The package semiconductors may have a structure in which memory chips and application specific integrated circuit (ASIC) chips are placed on the interposer and a molding member surrounds the memory chip and the ASIC chip.

An interposer wrapped with a molding member may be bonded to the package substrate through heat treatment. The interposer may experience warpage due to differences in thermal expansion coefficients. Accordingly, a non-wetting defect may occur, in which the bond between the interposer and the package substrate is not smooth.

### SUMMARY

Some example embodiments of inventive concepts provide a package semiconductor in which non-wetting defects, which may be caused by poor bonding between the interposer and the package substrate, may be minimized (or reduced) even if warpage occurs in the interposer.

Goals to be achieved by example embodiments of the present disclosure are not limited to the technical aspects described above, and other goals may be inferred from the following example embodiments.

Some example embodiments of inventive concepts provide a package semiconductor including a package substrate including a pad protruding from a single surface, an interposer arranged in a first direction perpendicular to the single surface of the package substrate, a column on a surface adjacent to the package substrate of the interposer, and arranged at a position corresponding to the pad, a solder arranged between the pad and the column, a first semiconductor chip on the interposer, and a second semiconductor chip on the interposer, and spaced apart from the first semiconductor chip, wherein the interposer includes a first area between the first semiconductor chip and the second semiconductor chip and a second area different than the first area, the solder includes a first solder having at least a portion at a position corresponding to the first area, and a second solder having at least a portion at a position corresponding to the second area, the column includes a first column in contact with the first solder and a second column in contact with the second solder, the pad includes a first pad at a position corresponding to the first solder and a second pad at a position corresponding to the second solder, and the first solder has a volume that is greater than a volume of the second solder.

Some example embodiments of inventive concepts provide a package semiconductor including a package substrate including a pad protruding from a single surface, a substrate insulation layer arranged in a first direction perpendicular to the single surface of the package substrate and configured to expose at least a portion of the pad, an interposer arranged in the first direction perpendicular to the single surface of the package substrate, a column on a surface adjacent to the package substrate of the interposer, and arranged at a position corresponding to the pad, a solder between the pad and the column, a first semiconductor chip on the interposer, and a second semiconductor chip on the interposer, and spaced apart from the first semiconductor chip, wherein the interposer includes a first area between the first semiconductor chip and the second semiconductor chip and a second area different than the first area, the solder includes a fist solder having at least a portion at a position corresponding to the first area, and a second solder having at least a portion at a position corresponding to the second area, the pad includes a first pad at a position corresponding to the first solder and a second pad at a position corresponding to the second solder, and a surface area of the first pad exposed from the substrate insulation layer when viewed from the first direction is greater than a surface area of the second pad that is exposed from the substrate insulation layer.

Some example embodiments of inventive concepts provide a package semiconductor including a package substrate including a pad protruding from a single surface, a substrate insulation layer arranged in a first direction perpendicular to the single surface of the package substrate and configured to expose at least a portion of the pad, an interposer arranged in the first direction perpendicular to the single surface of the package substrate, a column on a surface adjacent to the package substrate of the interposer, and arranged at a position corresponding to the pad, a solder between the pad and the column, a first semiconductor chip on the interposer, and a second semiconductor chip on the interposer, and spaced apart from the first semiconductor chip, wherein the interposer includes a first area between the first semiconductor chip and the second semiconductor chip, and a second area different than the first area, the solder includes a fist solder having at least a portion at a position corresponding to the first area, and a second solder having at least a portion at a position corresponding to the second area, the column includes a first column in contact with the first solder and a second column in contact with the second solder, the pad includes a first pad at a position corresponding to the first solder and a second pad at a position corresponding to the second solder, the first solder has a volume V1 that is greater than a volume V2 of the second solder, a ratio (V1/V2) of the volume V1 of the first solder and the volume V2 of the second solder is greater than 1 and less than or equal to 3, a surface area of the first pad exposed from the substrate insulation layer when viewed from the first direction is greater than a surface area of the second pad that is exposed from the substrate insulation layer, a ratio (A1/A2) of a surface area A1 of the first pad exposed from the substrate insulation layer and a surface area A2 of the second pad exposed from the substrate insulation layer is greater than 1 and less than or equal to 3, a contact angle between the first solder and a front side surface of the first column in the first direction facing the first pad is 140 degrees or greater than 140 degrees, the interposer includes a through via configured to penetrate the interposer along the first direction at a position corresponding to the column, and a spaced distance between the first column and the package substrate is greater than a spaced distance between the second column and the package substrate.

Additional aspects of example embodiments will be set forth in part in the description which follows and, in part, will be apparent from the description, or may be learned by practice of the disclosure.

According to some example embodiments, it may be possible to provide a package semiconductor in which non-wetting defects, in which the bond between the interposer and the package substrate is not smooth, may be minimized (or reduced) even if warpage occurs in the interposer.

Effects of the present disclosure are not limited to those described above, and other effects may be made apparent to those skilled in the art from the following description.

### BRIEF DESCRIPTION OF THE FIGURES

These and/or other aspects, features, and advantages of the present disclosure will become apparent and more readily appreciated from the following description of example embodiments, taken in conjunction with the accompanying drawings of which:

FIG. 1 is a cross-sectional view schematically illustrating a package semiconductor according to some example embodiments;

FIG. 2 is an enlarged view of a portion P of FIG. 1;

FIG. 3 is an enlarged view of a portion Q of FIG. 1;

FIG. 4 is a schematic plan view of a package substrate according to some example embodiments;

FIG. 5 illustrates an enlarged view of the first pad and an enlarged view of the second pad of FIG. 4;

FIG. 6 is a schematic plan view of a package substrate according to some example embodiments;

FIG. 7 illustrates an enlarged view of the first pad and an enlarged view of the second pad of FIG. 6;

FIG. 8 is a schematic plan view of a package substrate according to some example embodiments;

FIG. 9 is an enlarged view of the first pad and an enlarged view of the second pad of FIG. 8;

FIG. 10 is a cross-sectional view schematically illustrating a package semiconductor according to some example embodiments;

FIG. 11 and FIG. 12 are cross-sectional views schematically illustrating a package semiconductor to illustrate some of the processes for manufacturing the package semiconductor according to some example embodiments; and

FIG. 13 to FIG. 20 are cross-sectional views schematically showing a portion of a package semiconductor to explain a process for manufacturing a substrate solder formed on a package substrate according to some example embodiments.

### DETAILED DESCRIPTION

Terms or words used in the specification and claims may not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment.

, when an element is described as being “directly on,” “adjacent to” or “in contact with” another element, the element may be understood as being in direct contact with or connected to the another element, and it may be understood that there is no other element between the two.

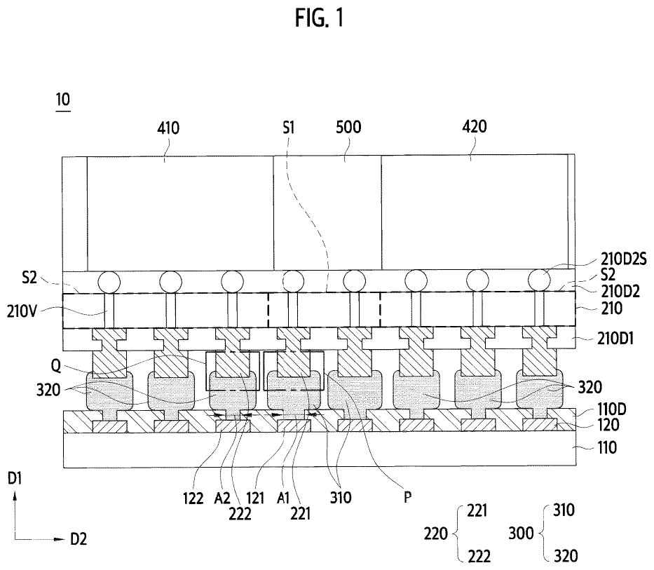

Further, in the present disclosure, when an element is described as being “on a upper portion” or “on a upper surface” of another element, it may be understood as existing above the vertical direction, for example, as being above the +D1 direction in the drawing (FIG. 1), and the two elements may be in direct contact or connected, but it may also be understood that another element exists between the two. The same is applied even when an element is described as being “above”another element in the present disclosure.

Further, in the present disclosure, when an element is described as being “on a lower portion” or “on a lower surface” of another element, it may be understood as existing below based on the vertical direction, for example, being further below based on the −D1 direction in the drawing (FIG. 1), and the two elements may be in direct contact or connected, but it may also be understood that another element exists between the two. The same is applied even when an element is described as being “below”another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side, and a back side are expressed based on the direction shown in the drawing. If the direction of the object changes, it may be expressed differently.

Further, in the specification and claims, terms including ordinal numbers such as “first,” “second,” etc., may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The drawings illustrated in the present disclosure are according to mere example embodiments, and the ratio of the width, the length and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “the same” as, or “equal” to other elements may be “the same” as, or “equal” to or “substantially the same” as or “substantially equal” to the other elements and/or properties thereof. Elements and/or properties thereof that are “substantially the same” as or “substantially equal” to other elements and/or properties thereof will be understood to include elements and/or properties thereof that are the same as, or equal to the other elements and/or properties thereof within manufacturing tolerances and/or material tolerances. Elements and/or properties thereof that are the same or substantially the same as other elements and/or properties thereof may be structurally the same or substantially the same, functionally the same or substantially the same, and/or compositionally the same or substantially the same.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and shapes should be construed as including a manufacturing or operational tolerance (e.g., ±10%) around the stated numerical values or shapes.

It will be understood that elements and/or properties thereof (e.g., structures, surfaces, directions, or the like), which may be referred to as being “perpendicular,” “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

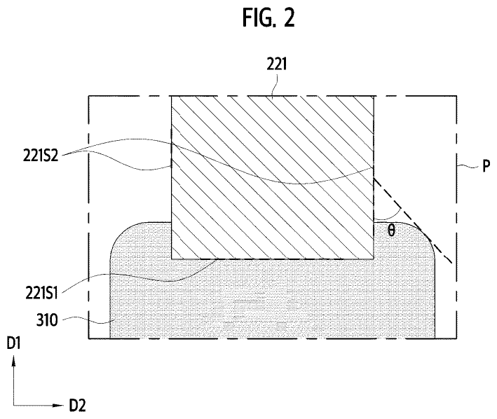

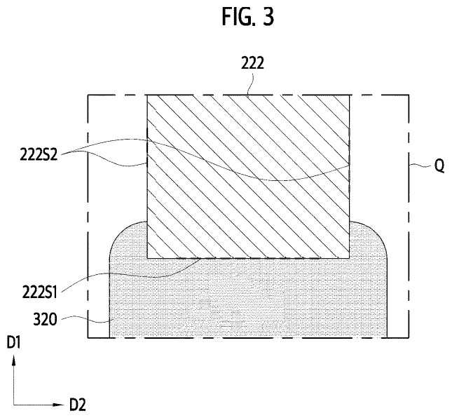

FIG. 1 is a cross-sectional view schematically illustrating a package semiconductor 10 according to some example embodiment. FIG. 2 is an enlarged view of the portion P of FIG. 1. FIG. 3 is an enlarged view of the portion Q of FIG. 1.

In some example embodiments, the package semiconductor 10 may include a package substrate 110, an interposer 210, a column 220, a solder 300, and semiconductor chips (a first semiconductor chip 410 and a second semiconductor chip 420).

Referring to FIG. 1, the first direction D1 may indicate a direction perpendicular to one surface of the package substrate 110, the second direction D2 may indicate a direction (that is parallel to one surface of the package substrate 110 and intersects the first direction D1, and the third direction D3 may indicate a direction that is parallel to one surface of the package substrate 110 and intersects each of the first direction D1 and the second direction D2.

In some example embodiments, the package substrate 110 may include a pad 120 formed (or arranged) to protrude from one surface. In the present disclosure, a single pad (e.g., a pad 120) may be referred to as “the pad 120,” and two or more pads (or two or more of “the pad 120”) may be referred to as “a plurality of pads 120” or “the pads 120.” In some example embodiments, the pad 120 may be electrically connected to the interposer 210 via the solder 300. In some example embodiments, the package substrate 110 may include the pad 120 formed to protrude from one surface in the first direction D1. In some example embodiments, the package substrate 110 may include a plurality of pads 120, and the plurality of pads 120 may be spaced from each other with a predetermined spacing (or a desired spacing). In some example embodiments, the plurality of pads 120 may be spaced from each other with a predetermined spacing (or a desired spacing) in the second direction D2.

In some example embodiments, the package substrate 110 may include an opposing pad (not illustrated) on one surface opposite to the surface on which the pad 120 is formed. In some example embodiments, there may be a plurality of opposing pads, the plurality of opposing pads may be arranged in the same number as the pads 120. In some example embodiments, each of the plurality of opposing pads may be placed in a position corresponding to each of the plurality of pads 120. In some example embodiments, the package substrate 110 may have a conductive pattern (not illustrated), and the conductive pattern may electrically connect the pad 120 and the opposing pad. In some example embodiments, the opposing pad may be electrically connected by making contact with external connection terminals.

In some example embodiments, the package substrate 110 is not particularly limited, but may be a silicon substrate, a semiconductor compound substrate, a plastic substrate, a glass substrate, or a ceramic substrate, but example embodiments are not limited thereto. In some example embodiments, the package substrate 110 may include an impurity region due to doping, although not illustrated separately, and a periphery circuit configured to select and control electronic components such as transistors or memory cells, but example embodiments are not limited thereto.

In some example embodiments, the pad 120 may contain a conductive material. In the present disclosure, the conductive material may include at least one of doped polysilicon, metal, conductive metal nitride, conductive metal silicide, and conductive metal oxide, but example embodiments are not limited thereto. In some example embodiments, the metal may include at least one of aluminum (Al), copper (Cu), titanium (Ti), tantalum (Ta), rubidium (Ru), tungsten (W), molybdenum (Mo), platinum (Pt), nickel (Ni), tin (Sn), lead (Pb) and cobalt (Co), but example embodiments are not limited thereto. In some example embodiments, the conductive metal nitride may include at least one of titanium aluminum nitride (TiAlN), tantalum silicon nitride (TaSiN) and rubidium titanium nitride (RuTiN), but example embodiments are not limited thereto. In some example embodiments, the conductive metal silicide may include at least one of titanium silicide (TiSi), tantalum silicide (TaSi), nickel silicide (NiSi), and cobalt silicide (CoSi), but example embodiments are not limited thereto. In some example embodiments, the conductive metal oxide may include at least one of iridium oxide (IrOx) and rubidium oxide (RuOx), but example embodiments are not limited thereto.

In some example embodiments, the package semiconductor 10 may include a substrate insulation layer 110D disposed on one surface of the package substrate 110. In some example embodiments, the substrate insulation layer 110D may be placed (or arranged) in the first direction D1 of the package substrate 110. In some example embodiments, the substrate insulation layer 110D may expose at least a portion of the pad 120. In some example embodiments, the substrate insulation layer 110D may expose a portion of the pad 120 while burying another portion of the pad 120. In some example embodiments, the substrate insulation layer 110D may include an insulating material. In the present disclosure, the insulating material is not particularly limited, but may include one or more of, for example, silicon oxide, silicon nitride, and silicon oxynitride, but example embodiments are not limited thereto.

In some example embodiments, the interposer 210 may be placed (or arranged) on one surface of the package substrate 110. In some example embodiments, the interposer 210 may be placed in the first direction D1 of the package substrate 110.

In some example embodiments, the column 220 may be formed on a surface adjacent to the package substrate 110 of the interposer 210, and be formed at a position corresponding to the pad 120. In some example embodiments, the column 220 may include a conductive material. In some example embodiments, the column 220 may contain copper (Cu), but example embodiments are not limited thereto. In some example embodiments, there may be a plurality of columns 220, and the plurality of columns 220 may be arranged in the same number as the pads 120. In some example embodiments, each of the plurality of columns 220 may be placed (or arranged) in a position corresponding to each of the plurality of pads 120.

In some example embodiments, the package semiconductor 10 may include a first insulation layer 210D1 disposed on one surface of the interposer 210. In some example embodiments, the package semiconductor 10 may include a second insulation layer 210D2 positioned opposite to the first insulation layer 210D1 with the interposer 210 therebetween. In some example embodiments, each of the first insulation layer 210D1 and the second insulation layer 210D2 may include an insulating material, but example embodiments are not limited thereto.

In some example embodiment, the first insulation layer 210D1 may embed part of the column 220, and the column 220 may include an area protruding from the surface of the first insulation layer 210D1. The protruding area of the column 220 may be electrically connected to the pad 120 via the solder 300, which will be described later. In some example embodiments, the second insulation layer 210D2 may include a second insulation layer solder 210D2S to electrically connect the interposer 210 and the semiconductor chips (the first semiconductor chip 410 and the second semiconductor chip 420) to each other. In some example embodiments, the second insulation layer solder 210D2S may be arranged to correspond to the column 220. Some example embodiments may include a plurality of second insulation layer solders 210D2S, and each of the plurality of second insulation layer solders 210D2S may be arranged to correspond to each of the plurality of columns 220. In some example embodiments, the interposer 210 may have a built-in through via 210V to electrically connect the column 220 and the second insulation layer solder 210D2S. For example, the interposer 210 may include the through via 210V penetrating the interposer 210 along the first direction D1 at a location corresponding to the column 220. In some example embodiments, the second insulation layer solder 210D2S may contain, but is not particularly limited to, one or more of tin (Sn) and lead (Pb), but example embodiments are not limited thereto. In some example embodiments, the through via 210V may contain a conductive material.

In some example embodiments, the solder 300 may be formed between the pad 120 and the column 220. Some example embodiments may include a plurality of solders 300. Each of the plurality of columns 220 may be placed (or arranged) in a position corresponding to each of the plurality of pads 120, and each solder 300 may be formed between the column 220 and its corresponding pad 120. In some example embodiments, the plurality of solders 300 may be arranged at a predetermined interval (or at a desired interval) from each other. In some example embodiments, the plurality of solders 300 may be arranged at a predetermined interval (or at a desired interval) from each other along the second direction D2. In some example embodiments, the solder 300 may contain, but is not specifically limited to, a conductive material. For example, the solder 300 may contain one or more of tin (Sn) and lead (Pb), but example embodiments are not limited thereto.

In some example embodiments, each of the pad 120, the column 220 and the solder 300 may contain a conductive material. In some example embodiments, the melting point of the solder 300 may be lower than at least one of the melting point of the pad 120 and the melting point of the column 220. In some example embodiments, the solder 300 may include a conductive material having a lower melting point than the conductive material contained in at least one of the pad 120 and the column 220.

In some example embodiments, the semiconductor chips may include the first semiconductor chip 410 and the second semiconductor chip 420, but example embodiments are not limited thereto. In some example embodiments, the package semiconductor 10 may include the first semiconductor chip 410 arranged on the interposer 210. In some example embodiments, the package semiconductor 10 may include the second semiconductor chip 420 positioned on the interposer 210 and spaced apart from the first semiconductor chip 410. In some example embodiments, each of the first semiconductor chip 410 and the second semiconductor chip 420 may be electrically connected to the interposer 210 via the second insulation layer solder 210D2S. In some example embodiments, each of the first semiconductor chip 410 and the second semiconductor chip 420 may include a terminal (not illustrated) including a conductive material that is bonded to the second insulation layer solder 210D2S. In some example embodiments, the first semiconductor chip 410 may include a single memory chip or a structure in which multiple memory chips are stacked. For example, the first semiconductor chip 410 may include a high bandwidth memory (HBM) chip, but example embodiments are not limited thereto. In some example embodiments, the second semiconductor chip 420 may include an ASIC chip, but example embodiments are not limited thereto.

In some example embodiments, the first semiconductor chip 410 and the second semiconductor chip 420 may be spaced apart from each other along the second direction D2. In some example embodiments, a dummy chip (not illustrated) or an insulation layer (not illustrated) may be placed between the first semiconductor chip 410 and the second semiconductor chip 420.

In some example embodiments, the package semiconductor 10 may include a molding layer 500 placed (or arranged) on the interposer 210 and surrounding the first semiconductor chip 410 and the second semiconductor chip 420. In some example embodiments, the molding layer 500 may wrap some outer surfaces of the interposer 210, the first semiconductor chip 410, and the second semiconductor chip 420. In some example embodiments, the molding layer 500 may wrap some outer surfaces of the first semiconductor chip 410 and the second semiconductor chip 420 such that the upper surfaces (e.g., the most spaced apart surface from the interposer 210 in the first direction D1) of the first semiconductor chip 410 and the second semiconductor chip 420 may be exposed. In some example embodiments, the molding layer 500 may include epoxy molding compound (EMC), but example embodiments are not limited thereto.

In some example embodiments, the interposer 210 may include a first area S1 between the first semiconductor chip 410 and the second semiconductor chip 420, and a second area S2 different than the first area S1.

In some example embodiments, the solder 300 may include a first solder 310 at least partially arranged at a position corresponding to the first area S1, and a second solder 320 at least partially arranged at a position corresponding to the second area S2. In some example embodiments, the column 220 may come into contact with the first solder 310 and the second solder 320. In some example embodiments, the column 220 may include a first column 221 in contact with the first solder 310, and a second column 222 that is in contact with the second solder 320. In some example embodiments, the pad 120 may include a first pad 121 positioned corresponding to the first solder 310, and a second pad 122 positioned corresponding to the second solder 320.

In some example embodiments, the volume V1 of the first solder 310 may be greater than the volume V2 of the second solder 320. In some example embodiments, the ratio (e.g., the volume V1/the volume V2) of the volume V1 of the first solder 310 and the volume V2 of the second solder 320 may be greater than approximately 1 and less than or equal to approximately 3, 1.01 or more and 2.5 or less, 1.02 or more and 2 or less, 1.03 or more and 1.75 or less, 1.04 or more and 1.5 or less, or 1.05 or more and 1.3 or less, but example embodiments are not limited thereto. Through this, even if warpage occurs in the interposer 210, smooth bonding (e.g., wetting) between the interposer 210 and the package substrate 110 may be achieved. In the present disclosure, the volume may be measured at room temperature and pressure, and specifically, the volume may be measured at approximately 25° C. and approximately 1 atm.

In some example embodiments, referring to FIG. 2, the contact angle (Θ) between the first solder 310 and a first column front side 221S1 may be greater than 140 degrees, but example embodiments are not limited thereto. In some example embodiments, the first column front side 221S1 may be a surface in the first direction D1 of the first column 221 facing the first pad 121. In some example embodiments, the contact angle (Θ) between the first solder 310 and the first column front side 221S1 may be 270 degrees or less than 270 degrees, but embodiments are not limited thereto. When the contact angle (Θ) between the first solder 310 and the first column front side 221S1 is within the above-mentioned range, it may be seen that the first solder 310 and the first column 221 are smoothly joined (e.g., wetted). In some example embodiments, the first solder 310 may contact at least a portion of a first column side 221S2, which may be a surface in the second direction D2 of the first column 221 (e.g., a side surface).

In some example embodiments, referring to FIG. 3, the contact angle between the second solder 320 and a second column front side 222S1 may be 140 degrees or greater, but example embodiments are not limited thereto. In some example embodiments, the second column front side 222S1 may be a surface in the first direction D1 of the second column 222 facing the second pad 122. In some example embodiments, the contact angle (Θ) between the second solder 320 and the second column front side 222S1 may be 270 degree or less, but embodiments are not limited thereto. When the contact angle (Θ) between the second solder 320 and the second column front side 222S1 is within the above described range, the second solder 320 and the second column 222 may be smoothly joined (e.g., wetted). In some example embodiments, the second solder 320 may contact at least a portion of a second column side 222S2, which may be a surface in the second direction D2 of the second column 222 (e.g., a side surface).

In some example embodiments, a surface area A1 of the first pad 121 exposed from the substrate insulation layer 110D when viewed from the first direction D1 may be larger than a surface area A2 of the second pad 122 exposed from the substrate insulation layer 110D.

In some example embodiments, the ratio (e.g., the surface area A1/the surface area A2) of the surface area A1 of the first pad 121 exposed from the substrate insulation layer 110D and the surface area A2 of the second pad 122 exposed from the substrate insulation layer 110D may be greater than approximately 1 and less than or equal to approximately 3, 1.01 to 2.5, 1.02 to 2, 1.03 to 1.75, 1.04 to 1.5, or 1.05 to 1.3, but example embodiments are not limited thereto. Through this, even if warpage occurs in the interposer 210, smooth bonding (e.g., wetting) may be achieved between the interposer 210 and the package substrate 110.

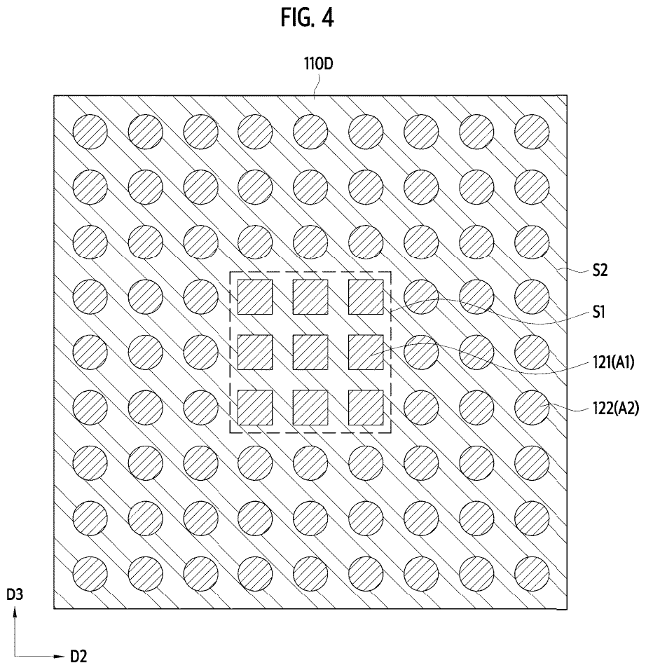

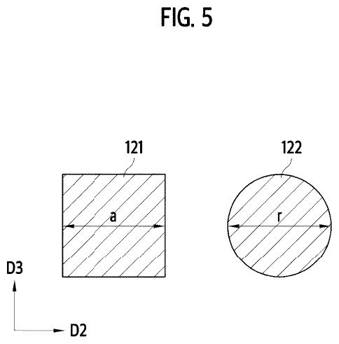

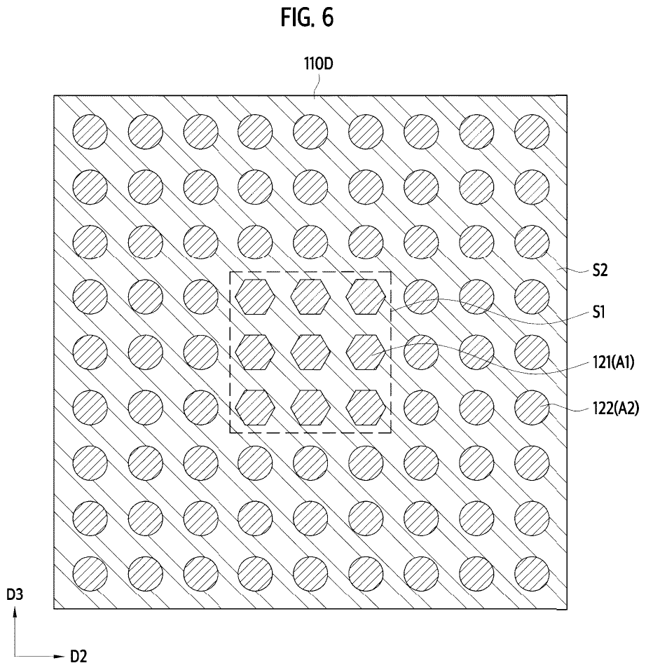

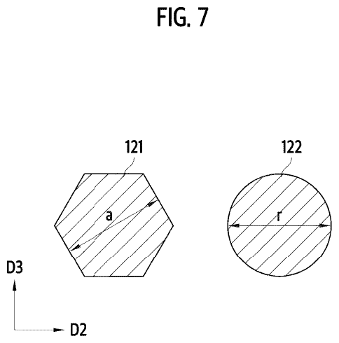

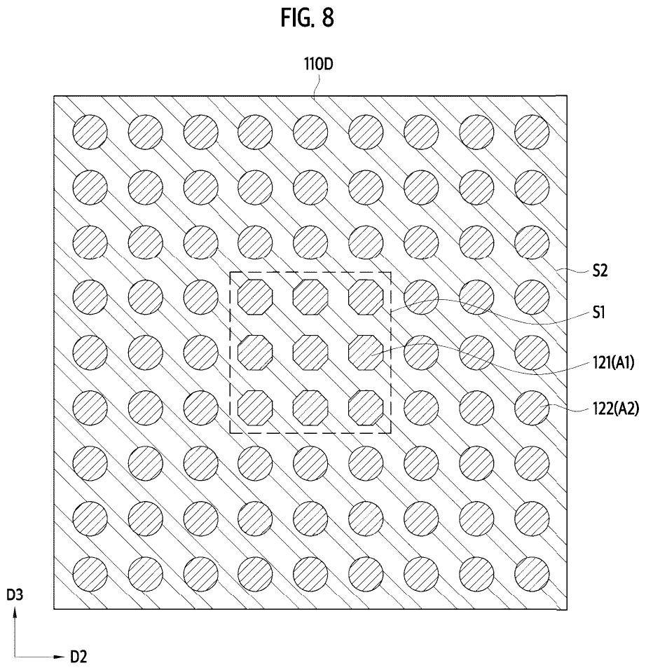

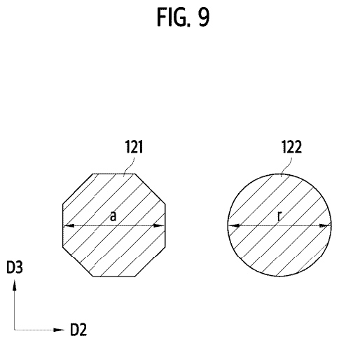

FIG. 4 is a schematic plan view of the package substrate 110 according to some example embodiments. FIG. 5 illustrates an enlarged view of the first pad 121 and an enlarged view of the second pad 122 of FIG. 4. FIG. 6 is a schematic plan view of a package substrate according to some example embodiments. FIG. 7 illustrates an enlarged view of the first pad and an enlarged view of the second pad of FIG. 6. FIG. 8 is a schematic plan view of a package substrate according to some example embodiments. FIG. 9 is an enlarged view of the first pad and an enlarged view of the second pad of FIG. 8.

In some example embodiments, the first pad 121 exposed from the substrate insulation layer 110D when viewed from the first direction D1 may be a polygon with four or more angles. Referring to FIG. 4 and FIG. 5, the first pad 121 exposed from the substrate insulation layer 110D when viewed from the first direction D1 may be rectangular. Referring to FIG. 6 and FIG. 7, the first pad 121 exposed from the substrate insulation layer 110D when viewed from the first direction D1 may be hexagonal. Referring to FIG. 8 and FIG. 9, the first pad 121 exposed from the substrate insulation layer 110D when viewed from the first direction D1 may be octagonal.

In some example embodiments, when viewed from the first direction D1, the second pad 122 exposed from the substrate insulation layer 110D may have a different shape from the first pad 121. In some example embodiments, the second pad 122 exposed from the substrate insulation layer 110D when viewed from the first direction D1 may be a circle or a polygon with more than four angles. In some example embodiments, when viewed from the first direction D1, in order for the surface area A1 of the first pad 121 exposed from the substrate insulation layer 110D to be larger than the surface area A2 of the second pad 122 exposed from the substrate insulation layer 110D, the shapes of the first pad 121 and the second pad 122 exposed from the substrate insulation layer 110D when viewed from the first direction D1 may be selected, respectively. Referring to FIG. 4 to FIG. 9, the second pad 122 exposed from the substrate insulation layer 110D when viewed from the first direction D1 may be circular.

In some example embodiments, the second pad 122 exposed from the substrate insulation layer 110D when viewed from the first direction D1 may be circular with a diameter r, and a distance a between the opposing edges of the first pad 121 exposed from the substrate insulation layer 110D may be equal to the diameter r of the second pad 122 exposed from the substrate insulation layer 110D. Through this, even if warpage occurs in the interposer 210, without increasing the size of the package semiconductor 10, smooth bonding (e.g., wetting) between the interposer 210 and the package substrate 110 may be achieved.

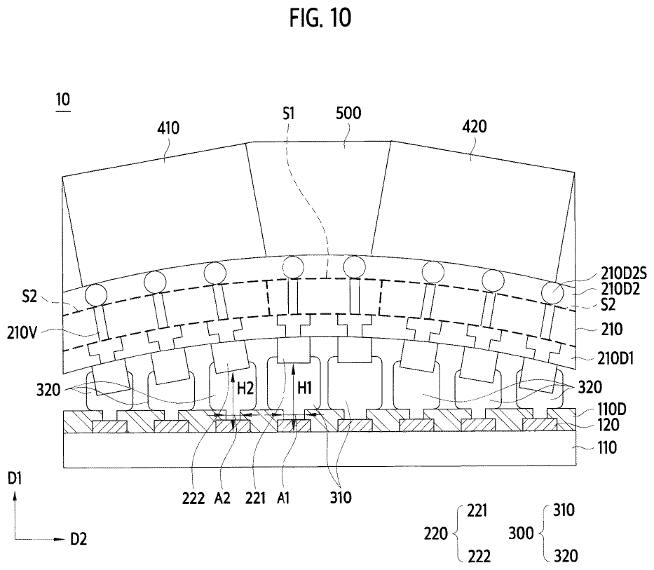

FIG. 10 is a cross-sectional view schematically illustrating the package semiconductor 10 according to some example embodiments. FIG. 10 is an exaggerated representation of cases where warpage deformation occurs due to various reasons in the interposer 210. With respect to the contents of FIG. 10, reference may be made to the descriptions with reference to FIG. 1 to FIG. 9, unless they are contradictory. In some example embodiments, the thermal expansion coefficient may differ due to differences in the configurations placed on the first area S1 and the second area S2 of the interposer 210, and when the interposer 210 and the package substrate 110 are bonded, warpage may occur in the interposer 210. In some example embodiments, in the package semiconductor 10, as described above, by making the volume of the first solder 310 greater than that of the second solder 320, the interposer 210 and the package substrate 110 may be smoothly bonded (e.g., wetted) even if warpage occurs.

In some example embodiments, the spaced distance H1 between the first column 221 and the package substrate 110 may be greater than the spaced distance H2 between the second column 222 and the package substrate 110. The spaced distance between the column 220 and the package substrate 110 may indicate (or specifically indicate) the distance (or minimum distance) between them with respect to the first direction D1. In some example embodiments, the package semiconductor 10 may enable (or ensure) smooth bonding (e.g., wetting) between the interposer 210 and the package substrate 110 even when warpage occurs in the interposer 210.

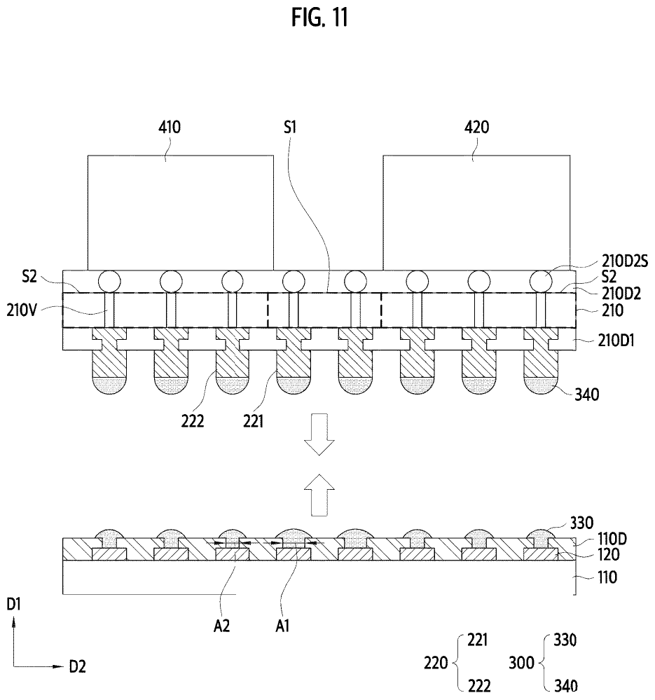

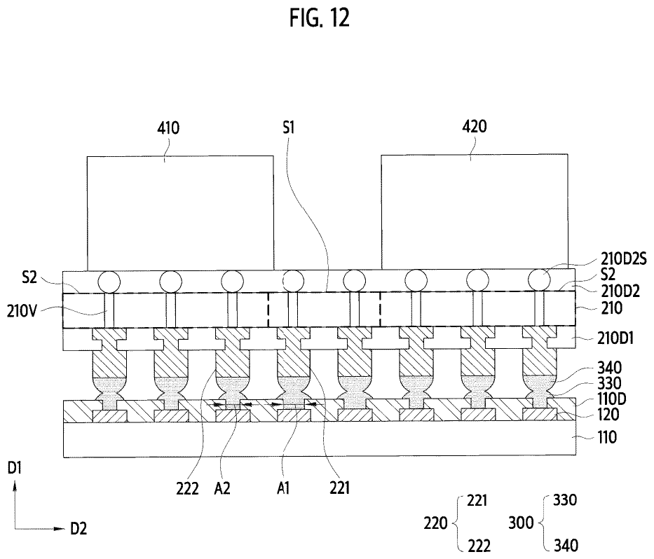

FIG. 11 and FIG. 12 are cross-sectional views schematically illustrating the package semiconductor 10 to illustrate some of the processes for manufacturing the package semiconductor 10 according to some example embodiments.

In some example embodiments, before the package substrate 110 and the interposer 210 are bonded, the solder 300 may include a substrate solder 330 that is contact with the pad 120 and formed protruding away in the direction away from the package substrate 110 (e.g., +D1 direction) from the pad 120, and an interposer solder 340 that is contact with the column 220 and formed by protruding away from the interposer 210 (e.g., −D1 direction) from the column 220. For example, the solder 300 may include the substrate solder 330 formed on the pad 120 and the interposer solder 340 formed on the column 220.

In some example embodiments, the solder 300 may be divided into the substrate solder 330 and the interposer solder 340 before the package substrate 110 and the interposer 210 are bonded (or wetted). In some example embodiments, when the package substrate 110 and the interposer 210 are bonded, the solder 300 may indicate a form which is formed by the substrate solder 330 and the interposer solder 340, each positioned at a corresponding position, being in contact with each other, fused, and hardened. In some example embodiments, when the package substrate 110 and the interposer 210 are bonded, heat treatment may be performed so that the substrate solder 330 and the interposer solder 340 may be melted. Heat treatment may be performed at temperatures above about 250° C., and the heat treatment may be performed at a temperature of about 500° C. or less, at which point the pad 120 and the column 220 do not melt, but example embodiments are not limited thereto.

In some example embodiments, there may be a plurality of interposer solders 340, and each of the plurality of interposer solders 340 may have the same volume. In some example embodiments, there may be the plurality of interposer solders 340. In some example embodiments, the volume of the interposer solder 340 placed at a position corresponding to the first area S1 may be greater than the volume of the interposer solder 340 placed at a position corresponding to the second area S2. In some example embodiments, the ratio of the volume of the substrate solder 330 placed at a position corresponding to the first area S1 and the volume of the substrate solder 330 placed at a position corresponding to the second area S2 may be greater than approximately 1 or less than or equal to approximately 3, 1.01 to 2.5, 1.02 to 2, 1.03 to 1.75, 1.04 to 1.5, or 1.05 to 1.3, but example embodiments are not limited thereto. Through this, even if warpage occurs in the interposer 210, smooth bonding (e.g., wetting) between the interposer 210 and the package substrate 110 may be achieved. In some example embodiments, each of the plurality of interposer solders 340 has the same volume, and the volume of the substrate solder 330 placed at a position corresponding to the first area S1 is larger than the volume of the substrate solder 330 placed at a position corresponding to the second area S2, and thus after the package substrate 110 and the interposer 210 are bonded, the volume of the first solder 310 may be larger than the volume of the second solder 320. For example, the reason the volume of the first solder 310 is greater than the volume of the second solder 320 is because the volume of the substrate solder 330 placed (or arranged) at a position corresponding to the first area S1 is larger than the volume of the substrate solder 330 placed at a position corresponding to the second area S2.

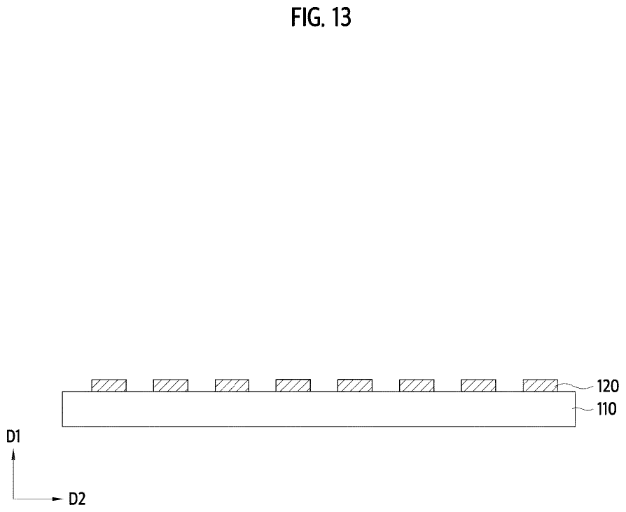

FIG. 13 to FIG. 20 are cross-sectional views schematically illustrating a portion of the package semiconductor 10 to explain a process for manufacturing the substrate solder 330 formed on a package substrate according to some example embodiments. With respect to the contents of FIG. 13 to FIG. 20 below, reference may be made to the descriptions in FIG. 1 to FIG. 12, unless they are contradictory.

Referring to FIG. 13, in some example embodiments, a method for manufacturing the package semiconductor 10 may include a process of manufacturing the substrate solder 330 formed on the package substrate 110. In some example embodiments, the process of manufacturing the substrate solder 330 may include forming the protruding pad 120 on a surface of the package substrate 110. In some example embodiments, there may be the plurality of pads 120, and each of the plurality of pads 120 may be placed with a certain spacing from each other. In some example embodiments, a pad seed layer (not illustrated) may be formed on the package substrate 110, a photosensitive pattern film may be formed on the pad seed layer, and then the pad 120 may be formed through an exposure and development process. However, the present disclosure is not limited thereto.

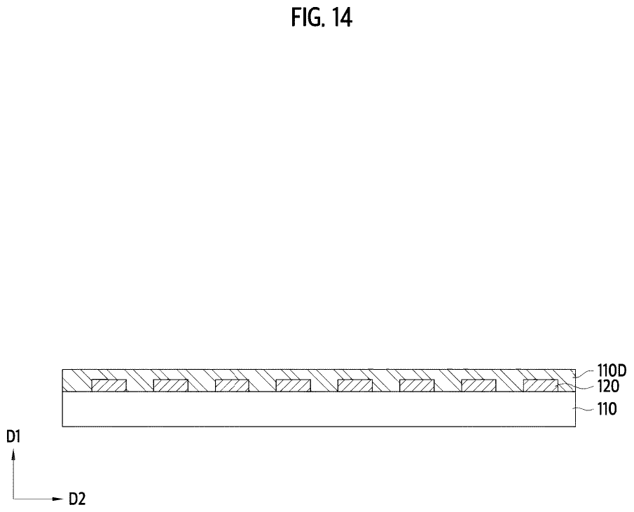

Referring to FIG. 14, in some example embodiments, the process of manufacturing the substrate solder 330 may include applying the substrate insulation layer 110D for the pad 120 to be embedded on the surface of the package substrate 110 on which the pad 120 is formed. In some example embodiments, the substrate insulation layer 110D may be referred to as a solder resist.

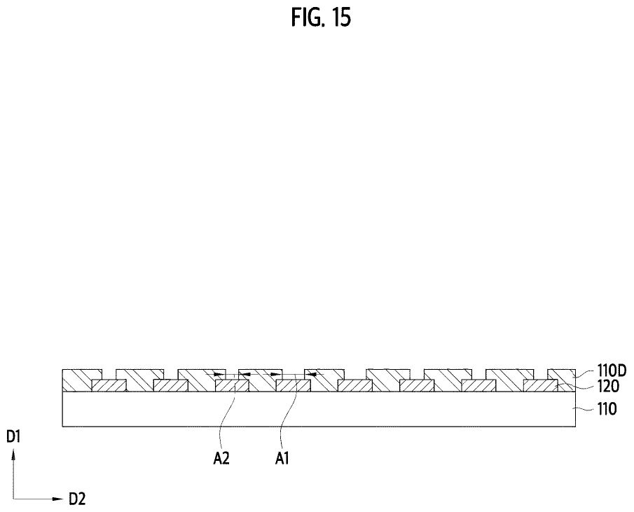

Referring to FIG. 15, in some example embodiments, the process for manufacturing the substrate solder 330 may include forming a photosensitive pattern film on the substrate insulation layer 110D and then performing an exposure and development process for the pad 120 to be exposed from the substrate insulation layer 110D. As described above, the pads 120 may include the first pad 121 positioned corresponding to the first area S1 and the second pad 122 positioned corresponding to the second area S2. The pads 120 may perform exposure and development processes such that the surface area A1 of the first pad 121 exposed from the substrate insulation layer 110D is larger than the surface area A2 of the second pad 122 exposed from the substrate insulation layer 110D when viewed from the first direction D1. In some example embodiments, when viewed from the first direction D1, the first pad 121 exposed from the substrate insulation layer 110D may be a polygon with four or more angles. In some example embodiments, when viewed from the first direction D1, the second pad 122 exposed from the substrate insulation layer 110D may have a different shape from the first pad 121, and the second pad 122 may be, for example, a circle or a polygon with more than 4 angles.

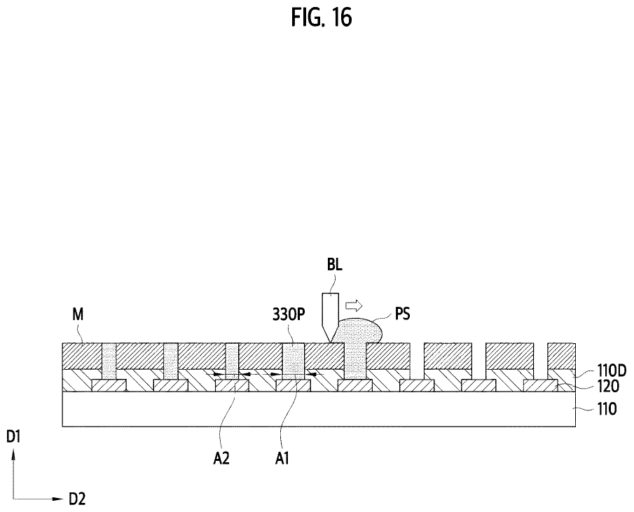

Referring to FIG. 16, in some example embodiment, the process for manufacturing the substrate solder 330 may include placing a mask M on the substrate insulation layer 110D and introducing a solder paste PS using a blade BL into an area where the pad 120 is exposed from the substrate insulation layer 110D to form a pre substrate solder 330P. In some example embodiments, stencil printing may be implemented as illustrated in FIG. 16, in which the solder paste PS is introduced from the pad 120 into the exposed area of the substrate insulation layer 110D. However, the present disclosure is not limited thereto.

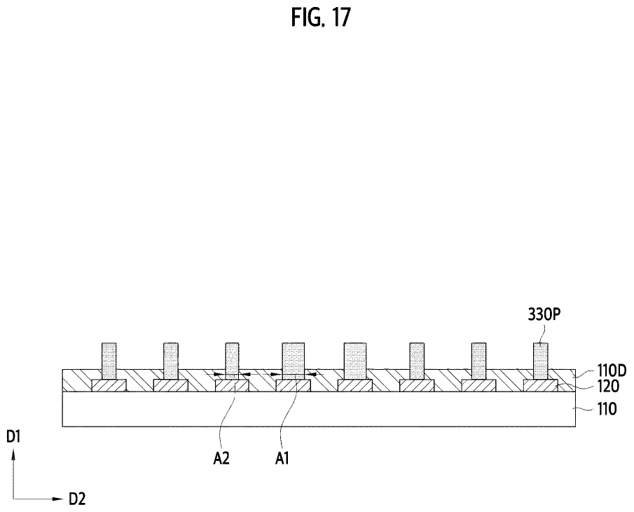

Referring to FIG. 17, in some example embodiments, the process of manufacturing the substrate solder 330 may include removing the mask M placed on the substrate insulation layer 110D. When the mask M is removed, the pre substrate solder 330P may be formed to protrude away from the package substrate 110 (e.g., +D1 direction) from the pad 120 while making contact with the pad 120.

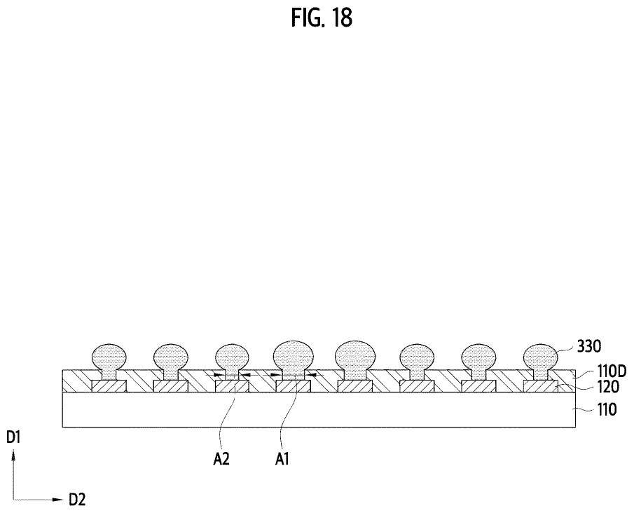

Referring to FIG. 18, in some example embodiments, the process of manufacturing the substrate solder 330 may include reflowing the pre substrate solder 330P formed on the package substrate 110. In some example embodiments, the reflow may include infrared reflow, hot air reflow and/or vacuum reflow. In some example embodiments, the pre substrate solder 330P may be formed into a round shape by swelling through reflow.

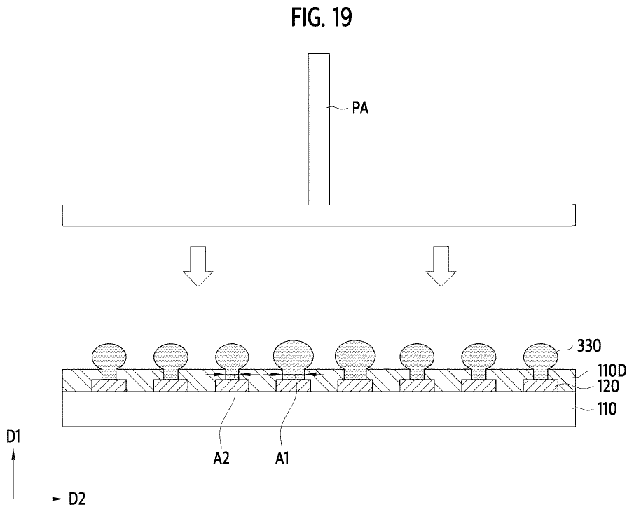

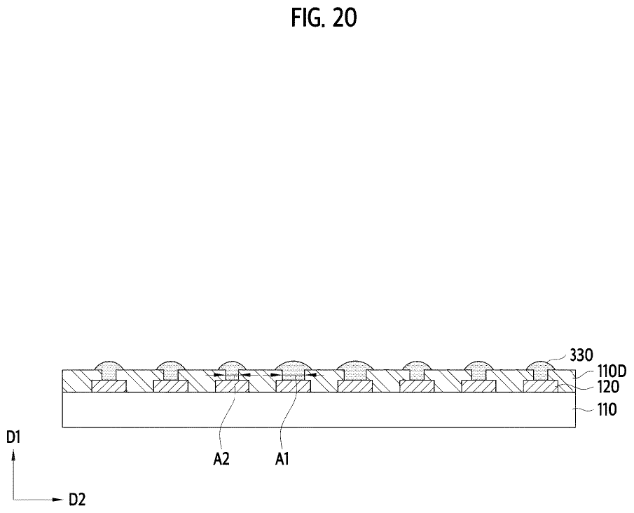

Referring to FIG. 19 and FIG. 20, in some example embodiments, the process of manufacturing the substrate solder 330 may include pressurizing the reflowed pre substrate solder 330P with a pressure apparatus PA to form the substrate solder 330.

Some example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. A package semiconductor comprising:
a package substrate including a pad protruding from a single surface;
an interposer arranged in a first direction perpendicular to the single surface of the package substrate;
a column on a surface adjacent to the package substrate of the interposer, and arranged at a position corresponding to the pad;
a solder arranged between the pad and the column;
a first semiconductor chip on the interposer; and
a second semiconductor chip on the interposer, and spaced apart from the first semiconductor chip,
wherein the interposer includes a first area between the first semiconductor chip and the second semiconductor chip, and a second area different than the first area,
wherein the solder includes a first solder having at least a portion at a position corresponding to the first area, and a second solder having at least a portion at a position corresponding to the second area,
wherein the column includes a first column in contact with the first solder and a second column in contact with the second solder,
wherein the pad comprises a first pad at a position corresponding to the first solder and a second pad at a position corresponding to the second solder, and
wherein the first solder has a volume that is greater than a volume of the second solder.

2. The package semiconductor of claim 1, wherein the first solder has volume V1 and the second solder has a volume V2,
wherein a ratio of the volume V1 and the volume V2 (V1/V2) is greater than 1 and less than or equal to 3.

3. The package semiconductor of claim 1, wherein a contact angle between the first solder and a front side surface of the first column in the first direction facing the first pad is degrees or greater than 140 degrees.

4. The package semiconductor of claim 3, wherein the first solder contacts at least a portion of a side surface of the first column in a second direction that is perpendicular to the first direction.

5. The package semiconductor of claim 4, wherein the second solder contacts at least a portion of a side surface of the second column in the second direction.

6. The package semiconductor of claim 1, wherein the interposer includes a through via configured to penetrate the interposer along the first direction at a position corresponding to the column.

7. The package semiconductor of claim 1, wherein a spaced distance between the first column and the package substrate is greater than a spaced distance between the second column and the package substrate.

8. The package semiconductor of claim 1, further comprising a substrate insulation layer on a single surface of the package substrate, and configured to expose at least a portion of the pad.

9. The package semiconductor of claim 8, wherein, when viewed from the first direction, the first pad exposed from the substrate insulation layer is a polygon with four or more angles, and the second pad exposed from the substrate insulation layer has a different shape than the first pad.

10. The package semiconductor of claim 1, wherein each of the pad, the column, and the solder include a conductive material.

11. The package semiconductor of claim 1, wherein a melting point of the solder is lower than at least one of a melting point of the pad and a melting point of the column.

12. The package semiconductor of claim 1, further comprising a molding layer on the interposer, and configured to surround the first semiconductor chip and the second semiconductor chip.

13. A package semiconductor comprising:
a package substrate including a pad protruding from a single surface;
a substrate insulation layer arranged in a first direction perpendicular to the single surface of the package substrate and configured to expose at least a portion of the pad;
an interposer arranged in the first direction perpendicular to the single surface of the package substrate;
a column on a surface adjacent to the package substrate of the interposer, and arranged at a position corresponding to the pad;
a solder between the pad and the column;
a first semiconductor chip on the interposer; and
a second semiconductor chip on the interposer, and spaced apart from the first semiconductor chip,
wherein the interposer includes a first area between the first semiconductor chip and the second semiconductor chip, and a second area different than the first area,
wherein the solder comprises a first solder having at least a portion at a position corresponding to the first area, and a second solder having at least a portion at a position corresponding to the second area,
wherein the pad includes a first pad at a position corresponding to the first solder and a second pad at a position corresponding to the second solder, and
wherein a surface area of the first pad exposed from the substrate insulation layer when viewed from the first direction is greater than a surface area of the second pad that is exposed from the substrate insulation layer.

14. The package semiconductor of claim 13, wherein the first pad exposed from the substrate insulation layer has a first surface area A1 and the second pad exposed from the substrate insulation layer has a second surface area A2,
wherein a ratio of the first surface area A1 and the second surface area A2 (A1/A2) is greater than 1 and less than or equal to 3.

15. The package semiconductor of claim 13, wherein the first solder has a first volume that is greater than a second volume of the second solder.

16. The package semiconductor of claim 13, wherein the column includes a first column in contact with the first solder and a second column in contact with the second solder, and
wherein the first solder contacts at least a portion of a side surface of the first column in a second direction that is perpendicular to the first direction.

17. The package semiconductor of claim 16, wherein the second solder contacts at least a portion of a side surface of a second column in the second direction.

18. The package semiconductor of claim 13, wherein,
when viewed from the first direction,
the first pad exposed from the substrate insulation layer is a polygon with four or more angles.

19. The package semiconductor of claim 18, wherein,
when viewed from the first direction,
the second pad exposed from the substrate insulation layer is circular, and
a distance between opposing edges of the first pad exposed from the substrate insulation layer is equal to a diameter of the second pad exposed from the substrate insulation layer.

20. A package semiconductor comprising:
a package substrate including a pad protruding from a single surface;
a substrate insulation layer arranged in a first direction perpendicular to the single surface of the package substrate and configured to expose at least a portion of the pad;
an interposer arranged in the first direction perpendicular to the single surface of the package substrate;
a column on a surface adjacent to the package substrate of the interposer, and arranged at a position corresponding to the pad;
a solder between the pad and the column;
a first semiconductor chip on the interposer; and
a second semiconductor chip on the interposer, and spaced apart from the first semiconductor chip,
wherein the interposer includes a first area between the first semiconductor chip and the second semiconductor chip and a second area different than the first area,
wherein the solder includes a first solder having at least a portion a position corresponding to the first area, and a second solder having at least a portion at a position corresponding to the second area,
wherein the column includes a first column in contact with the first solder and a second column in contact with the second solder,
wherein the pad includes a first pad at a position corresponding to the first solder and a second pad at a position corresponding to the second solder,
wherein the first solder has a volume V1 that is greater than a volume V2 of the second solder,
wherein a ratio (V1/V2) of the volume V1 of the first solder and the volume V2 of the second solder is greater than 1 and less than or equal to 3,
wherein a surface area of the first pad exposed from the substrate insulation layer when viewed from the first direction is greater than a surface area of the second pad that is exposed from the substrate insulation layer,
wherein a ratio (A1/A2) of a surface area A1 of the first pad exposed from the substrate insulation layer and a surface area A2 of the second pad exposed from the substrate insulation layer is greater than 1 and less than or equal to 3,
wherein a contact angle between the first solder and a front side surface of the first column that is a surface in the first direction facing the first pad is 140 degrees or greater than 140 degrees,
wherein the interposer comprises a through via configured to penetrate the interposer along the first direction at a position corresponding to the column, and
wherein a spaced distance between the first column and the package substrate is greater than a spaced distance between the second column and the package substrate.
